(19) United States
(12) Patent Application Publication
(10) Pub. No.: US 2026/0068538 A1
(43) Pub. Date: Mar. 5, 2026

(54) DEVICE AND MANUFACTURING METHOD THEREOF

(71) Applicant: NEC Corporation, Minato-ku, Tokyo (JP)

(72) Inventor: Ayuka TADA, Tokyo (JP)

(73) Assignee: NEC Corporation, Minato-ku, Tokyo (JP)

(21) Appl. No.: 18/791,535

(22) Filed: Aug. 1, 2024

(30) Foreign Application Priority Data
Aug. 9, 2023 (JP) 2023-130333

(51) Int. Cl. H10N 60/82; H01L 23/00; H10N 60/81

(52) U.S. Cl. CPC H10N 60/82; H10N 60/815

(57) ABSTRACT

A device manufacturing method includes: forming a conductive layer, which is to be an air bridge, on a sacrificial layer in a first surface of a chip to pattern form the conductive layer; removing the sacrificial layer other than the sacrificial layer underneath the air bridge; mounting the chip with the sacrificial layer left underneath the air bridge on a board such that the first surface of the chip opposes the board; and removing the sacrificial layer left underneath the air bridge.

### FIELD

The present invention is based upon and claims the benefit of the priority of Japanese patent application No. 2023-130333, filed on Aug. 9, 2023, the disclosure of which is incorporated herein in its entirety by reference thereto.

The present invention relates to a device and a manufacturing method thereof.

### BACKGROUND

A superconducting quantum circuit includes, as one of its basic elements, a superconducting resonator including an inductor and a capacitor, each of which is made of superconducting metal, and a SQUID (Super Quantum Interference Device) having a loop with at least one Josephson junction disposed therein. A Josephson junction is a tunnel junction between two superconducting layers separated by a thin layer made from an insulating material and behaves as a non-linear inductor. A resonance frequency of the superconducting resonator may be changed by modulating a magnetic flux penetrating the SQUID loop using a DC current and/or AC current signal flowing through a control line (a pump line). In a superconducting quantum circuit, a coplanar waveguide may be used as signal transmission in which a pair of ground planes (ground patterns) are arranged via respective gaps from a signal line along longitudinal sides of the signal line, all in a same plane. A chip including a plurality of superconducting circuits and may be configured to include a plurality of SQUIDs. In this configuration, a crosstalk may become a problem in which a magnetic field applied to a target SQUID is also applied to other SQUIDs.

For example, PTLs (Patent Literatures) 1 and 2 disclose a configuration in which an air bridge(s) is(are) arranged on a superconducting wiring layer of a board. In this configuration, ground planes (ground patterns) arranged in a same plane on both longitudinal sides of a signal line via respective gaps from the signal line constituting a coplanar waveguide are connected by a superconducting air bridge. According to PTL 1, the superconducting air bridge can contribute to reduce a crosstalk which may conceivably be due to distribution of electric charge along edges of ground planes arranged via respective gaps on both sides of the signal line. As a method for manufacturing a suspended conductor structure such as a metal (conductive) air bridge, which connects two separate portions in a pattern formed conductive layer on a board, PTL 2 discloses a method in which the metal (conductive) air bridge with an interlayer dielectric (ILD) such as a silicon dioxide for supporting the structure from underneath, and then the interlayer dielectric is removed.

### CITATION LIST

PTL 1: Japanese Patent No. 6437607

PTL 2: Japanese National Publication of International Patent Application No. 2020-532866

### SUMMARY

An object of the present disclosure is to provide a device manufacturing method and a device, each enabling a chip including an air bridge to be flip-chip mounted.

A device manufacturing method in an aspect of the present disclosure includes:
forming(depositing) a conductive layer, which is to be an air bridge, on a sacrificial layer in a first surface of a chip to pattern form the conductive layer;
removing the sacrificial layer other than the sacrificial layer underneath the air bridge;
mounting the chip with the sacrificial layer left underneath the air bridge on a board, with the first surface of the chip opposed to the board; and
removing the sacrificial layer left underneath the air bridge.

A device in another aspect of the present disclosure includes: a chip with at least one air bridge formed on a first surface of the chip; and a board with the chip mounted thereon, the first surface of the chip opposed to the board.

According to the present disclosure, a chip including an air bridge can be flip-chip mounted on a board.

### BRIEF DESCRIPTION OF DRAWINGS

FIGS. 1A to 1D are diagrams schematically illustrating manufacturing steps according to one of examples of the present disclosure.

FIGS. 2E to 2H are diagrams schematically illustrating manufacturing steps according to one of examples of the present disclosure.

FIG. 3 is a diagram schematically illustrating an example of mounting of the present disclosure.

FIG. 4 is a diagram schematically illustrating an example superconducting circuit apparatus of the present disclosure.

FIG. 5 is a diagram schematically illustrating another example of mounting of the present disclosure.

FIG. 6 is a diagram schematically illustrating another example of the superconducting circuit apparatus of the present disclosure.

FIGS. 7A to 7C are diagrams schematically illustrating examples of the present disclosure.

FIG. 8 is a diagram schematically illustrating one of examples of a superconducting circuit including air bridges of the present disclosure.

FIG. 9 is a diagram schematically illustrating one of examples of the superconducting circuit including the air bridges of the present disclosure.

FIG. 10 is a diagram schematically illustrating an example of an air bridge.

FIG. 11 is a diagram schematically illustrating an example of surface activated bonding.

### EXAMPLE EMBODIMENTS

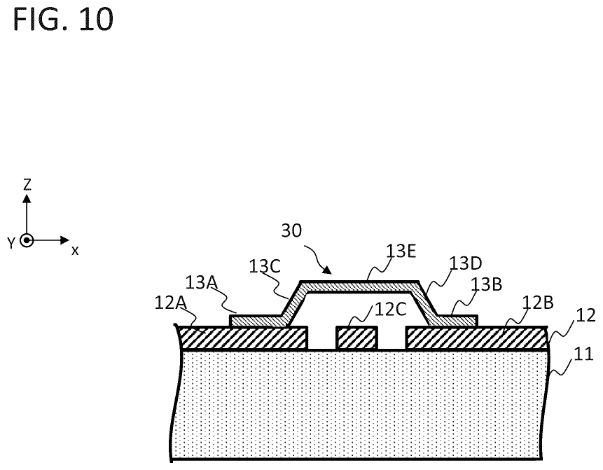

In the following description of examples and embodiments, reference is made to the accompanying drawings which form a part hereof, and in which it is shown by way of illustration specific examples that can be practiced. It is to be understood that other examples can be used and structural changes can be made without departing from the scope of the disclosed examples. It is noted that in the disclosure, the expression “at least one of A and B” means A, B, or (A and B). The term expressed as “—(s)” includes both singular and/or plural form. An air bridge is generally used as a three-dimensional wiring structure in which air on a board is used as an insulator. As schematically illustrated in FIG. 10, an air bridge 30 extending above a conductor 12C on a board 11 and connecting a first conductor 12A and a second conductor 12B includes contact parts (bases) 13A and 13B extending on the first conductor 12A and the second conductor 12B, respectively, bridge pier parts 13C and 13D, each of which rises from a corresponding one of the contact parts 13A and 13B in a direction to the other bridge pier part, and a bridge girder part 13E, two ends of which are supported by their respective bridge pier parts 13C and 13D. The contact parts 13A and 13B, the bridge pier parts 13C and 13D, and the bridge girder part 13E of the air bridge 30 may be integrally formed by a single conductive layer (a conductive film). In FIG. 10, for the sake of description of parts of the air bridge, outlines of the bridge pier parts 13C and 13D, the bridge girder part 13E, etc., are illustrated by straight lines. However, the outline may have a smoothly curved arch shape. A conductive layer, which is to serve as the air bridge, is deposited on a sacrificial layer (not illustrated) on the board 11 and pattern formed. Next, by removing the sacrificial layer, the air bridge 30 is formed. There is an air gap underneath the air bridge 30. Therefore, the air bridge 30 is physically fragile. For example, the air bridge 30 easily breaks by ultrasonic cleaning, which is one of the commonly used cleaning methods. Thus, it is difficult to carry out a process on the air bridge 30 after the sacrificial layer is removed. In addition, it is difficult to flip-chip mount a chip having the air bridge 30 on an interposer (also referred to as “interposer board”) or the like (it is difficult to invert (flip) and mount a chip).

The following describes some studies of an example in which a chip is flip-chip mounted on an interposer. An oxide film (a silicon oxide film) may be used as a sacrificial layer, and the sacrificial layer immediately under an air bridge is left to increase strength of the air bridge.

In a device in which a chip is flip-chip mounted on an interposer, for example, HF (hydrogen fluoride) is used for removing a silicon oxide film (a sacrificial layer) left under an air bridge of the chip. When etching is performed on the silicon oxide film (the sacrificial layer) by using hydrofluoric acid solution, hydrofluoric acid may damage a metal layer (a conductive layer), etc. For example, an Al (aluminum) film constituting a Josephson junction, a superconducting wiring, an electrode, etc., arranged in a wiring layer of a quantum chip, are eroded. It might be particularly problematic if a Josephson junction (Al/Al oxide film/Al), which is a quantum circuit element of a quantum chip, is eroded and is lost by the HF. When Al, Cu (copper), Ti (titanium), or the like is used for wirings, electrodes, bumps, etc. in the interposer, these may be eroded (Al, Cu, Ti are eroded by hydrofluoric acid. For example, Nb (niobium), which is used as a superconducting wiring material, is little eroded. Au (gold) is not eroded). By using vapor HF (vapor hydrogen fluoride: HF solution is evaporated), the erosion of these metal layer (conductive layer) can be relatively reduced. However, when vapor-phase etching is performed by using hydrofluoric acid vapor evaporated from hydrofluoric acid solution, even with VHF, strict etching conditions need to be set, not only to prevent adherence of reaction product, but also to completely remove the silicon oxide film (the sacrificial layer) immediately underneath the air bridge. Thus, one can assume that it is difficult to set an optimal process condition range (a process window) that prevents erosion of the metal by HF and that removes the sacrificial layer. Thus, it is conceivably difficult to remove a silicon oxide film (a sacrificial layer) left under an air bridge by using HF or Vapor HF in a state in which a quantum chip having the air bridge has been flip-chip mounted on an interposer. The above-described problem is an example. The present disclosure discloses a method and a device that may contribute to solve the above-described problem, though not limited thereto and to enable flip-chip mounting of a chip including an air bridge.

According to the present disclosure, a conductive layer, which is to be an air bridge, is deposited on a sacrificial layer in a first surface of a chip, and pattern formed. Next, the sacrificial layer other than the sacrificial layer underneath the air bridge is removed, and the chip with the sacrificial layer left underneath the air bridge is mounted (flip-chip mounted) on a board such that the first surface opposes the board (the board may be an interposer board or may be a board including a second chip). Next, the sacrificial layer left underneath the air bridge is removed. In this way, it is possible to obtain a device including the chip, which includes at least one air bridge on its first surface and which is mounted (flip-chip mounted) on the board such that the first surface opposes the board. The following describes some implementations of the present disclosure.

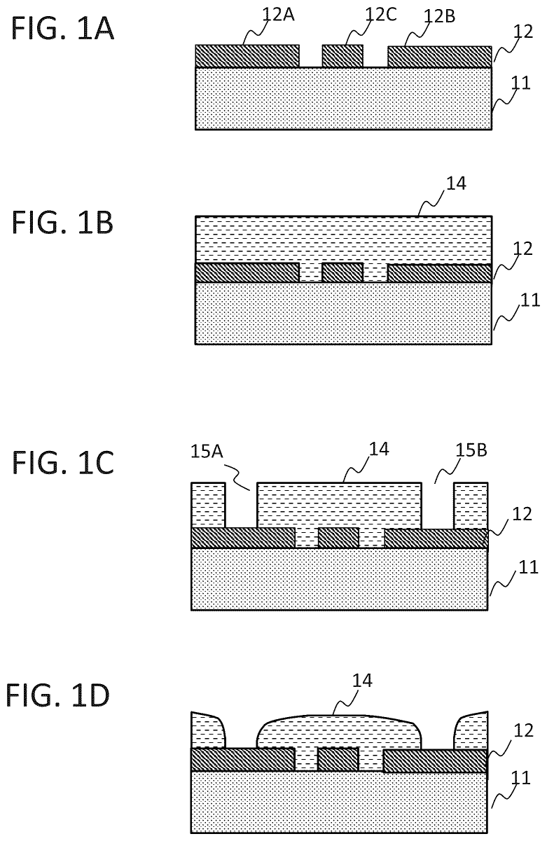

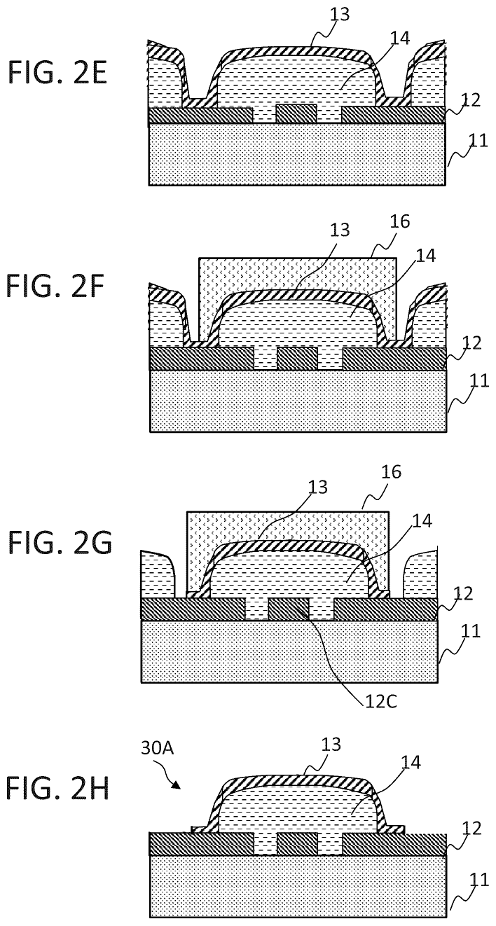

FIGS. 1A to 2H are sectional views schematically illustrating an example manufacturing process of an air bridge in which a quantum chip is manufactured by using a semiconductor process.

FIG. 1A schematically illustrates a state in which a wiring pattern is formed on a first surface (a front surface) of a board 11. A superconducting film 12 made of niobium (Nb) or the like is deposited on a first surface of a board 11, and pattern formed to a desired wiring pattern by exposure and development (photolithography)/etching. For example, a Nb wiring(s) as a superconducting wiring(s) and a Josephson junction(s) are formed. The Josephson junction may have a structure of Al/Al oxide film/Al laminated by oblique deposition, for example. In the following steps, an air bridge is manufactured. Hereinafter, a wiring layer on the first surface of the board 11 will be designated by reference numeral 12, which is the same reference numeral designating the superconducting film. In the wiring layer 12 on the first surface of the board 11, a first conductor 12A and a second conductor 12B are formed on either side of a conductor 12C (a signal conductor) with a predetermined gap from the conductor 12C. An air bridge not illustrated strides over the conductor 12C (the signal conductor) to electrically connect the first conductor 12A and the second conductor 12B. The conductor 12C (the signal conductor) and the first conductor 12A and the second conductor 12B in FIG. 1A may correspond to the conductor 12C (a signal conductor) and the first conductor 12A and the second conductor 12B (connected to each other by the air bridge 30) in FIG. 10, respectively. The first conductor 12A and the second conductor 12B may be ground planes (ground patterns). A waveguide in which the ground planes (the first conductor 12A and the second conductor 12B) disposed on each longitudinal side of the conductor 12C (the signal conductor) via a gap from the conductor 12C constitutes a coplanar waveguide (CPW). Connecting the first conductor 12A and the second conductor 12B which are separated from the conductor 12C (the signal conductor) with an air bridge is effective in reduction of crosstalk.

The board 11 may be made of silicon. The board 11 may, as a matter of course, be made of another electronic material such as germanium, sapphire, or compound semiconductor materials (group 4 elements (GeSn, etc.,), group III-V compounds (GaAs, GaN, GaP, GaSb, InAs, InP, InS, etc.,), or group II-VI compounds (ZnS, ZnSe, etc.,)). It is desirable that the material be monocrystalline. However, the material may alternatively be polycrystalline or amorphous.

The superconductor is made of a superconducting material such as Nb. The superconducting material is not limited to niobium (Nb). The superconducting material may be niobium nitride, aluminum (Al), indium (In), lead (Pb), tin (Sn), rhenium (Re), palladium (Pd), titanium (Ti), titanium nitride (TiN), tantalum (Ta), tantalum nitride (TaN), an alloy that contains at least one of these kinds of elements and that exhibits superconducting properties, or a laminated structure of these elements.

Referring to FIG. 1B, a photoresist 14 (e.g., photosensitive polyimide) used to form an air bridge is coated (applied) on an entire surface of the board 11 in FIG. 1A. Using a spin coat technique or the like, the photoresist 14 is uniformly applied to the entire surface of the board such that the photoresist 14 has a film thickness of from, for example, few micrometers (μ m) to ten to several tens of μ m in correspondence with a height of the air bridge.

Next, as illustrated in FIG. 1C, to form bridge piers 13C and 13D and contact parts 13A and 13B of the air bridge (see FIG. 10), vias 15A and 15B reaching the superconducting film 12 are formed by performing exposure and development on the photoresist 14 using a photomask of a desired pattern. The pattern formed photoresist 14 is termed as a “sacrificial layer”.

Next, as illustrated in FIG. 1D, the board 11 is heated to perform a reflow process on the photoresist 14. A reflow apparatus not illustrated (e.g., a hot plate) uniformly heats the board 11. Thus, the photoresist 14 (sacrificial layer) that has been pattern formed in the exposure and development step in FIG. 1C is heated, and softened to be caused to flow. As a result, an outline form of a cross-section of the photoresist 14 is rounded and has an arch-like shape.

Next, as illustrated in FIG. 2E, a superconducting member 13, which is to serve as the air bridge, is deposited on the photoresist 14 (sacrificial layer) that has been pattern formed on the board 11. As a not-limiting example, the superconducting member 13 may be made of aluminum (Al). The film thickness of the superconducting member 13 may be, for example, on the order of several hundred nm (nanometers) (1 μ m or less).

Next, as illustrated in FIG. 2F, a photoresist 16 is coated, and exposure and development are performed on the photoresist 16, using a desired photomask, such that the photoresist 16 is pattern formed to a pattern that matches a planar shape of the air bridge (photomask has a pattern for forming the air bridge).

As illustrated in FIG. 2G, the superconducting member 13 (Al) is etched, by using the photoresist 16 left on the superconducting member 13, as an etching mask. As a result, the superconducting member 13 is pattern formed to a wiring of the air bridge. That is, the air bridge which is a wiring of the superconducting member 13, is formed to stride over the conductor 12C via the photoresist 14 (sacrificial layer) left under the superconducting member 13. The etching of the superconducting member 13(Al) is not limited to the above-described example. For example, wet etching using acid such as a mixed acid or alkaline water solution such as developer, milling using Ar ions or the like, or reactive ion etching (RIE) using chlorine-based (Cl) gas may alternatively be used. FIG. 2G illustrates a state after etching of the superconducting member 13(Al), where the photoresist 16 is left upon the superconducting member 13, which is to serve as the air bridge. The entire photoresist 14 (sacrificial layer) is also left.

From the state illustrated in FIG. 2G, the photoresist 16 and the photoresist 14 (sacrificial layer) other than the photoresist 14 under the superconducting member 13 which is to serve as the air bridge, are removed simultaneously. As a result, a state illustrated in FIG. 2H is obtained. For example, ashing is performed to remove a hardened layer of the photoresists 14 and 16 that are exposed on surface. Next, for example, the photoresist 16 and the photoresist 14 (sacrificial layer) that is other than the photoresist 14 under an air bridge 30A are removed by immersion into an organic solvent, for several minutes. That is, removal of the photoresist 16 and the photoresist 14 (sacrificial layer) is performed in two stages.

First, the hardened layer of the photoresist 16 and the photoresist 14 (sacrificial layer) that is other than the photoresist 14 underneath the air bridge 30A and exposed on the front surface are removed by ashing or the like. When oxygen plasma reacts to the photoresist 14 (sacrificial layer) and the photoresist 16, CO₂, H₂ O, and O₂ are generated as gas. That is, the photoresist 14 (sacrificial layer) and the photoresist 16 are removed as gas. By dry ashing using oxygen plasma (by emitting oxygen plasma in a high energy state to a resin front surface, the oxygen plasma is made to combine with carbon constituting the resin, and the resin is vaporized and decomposed as CO₂), the hardened layer formed on front surfaces of the photoresist 16 and photoresist 14 at the formation of the Al bridge (e.g.,, a photosensitized portion which is exposed at the time of the exposure is hardened) is removed. Next, the photoresist 16 and the photoresist 14 (sacrificial layer) are removed by organic solvent. As long as the immersion into the organic solvent is performed within a predetermined time (e.g., several minutes), the photoresist 14 underneath the air bridge 30A is not completely dissolved but remains, while the photoresist 14 (sacrificial layer) that is other than the photoresist 14 underneath the air bridge 30 and exposed on surface is removed. As a result, as illustrated in FIG. 2H, a state in which the photoresist 14 (sacrificial layer) is left underneath the air bridge 30A is obtained.

The photoresist 14 (sacrificial layer) left underneath the air bridge 30A serves as a reinforcing member which supports the air bridge from underneath. Compared with a hollow air bridge, the example air bridge of the present disclosure has an improved mechanical strength. Thus, even when other processes such as cleaning and assembly are subsequently performed, the photoresist 14 (sacrificial layer) underneath the air bridge 30A prevents buckling or collapse of the air bridge, for example. Thus, processes such as additional cleaning on a quantum chip 10 and flip-chip mounting of the quantum chip 10 on an interposer can be performed.

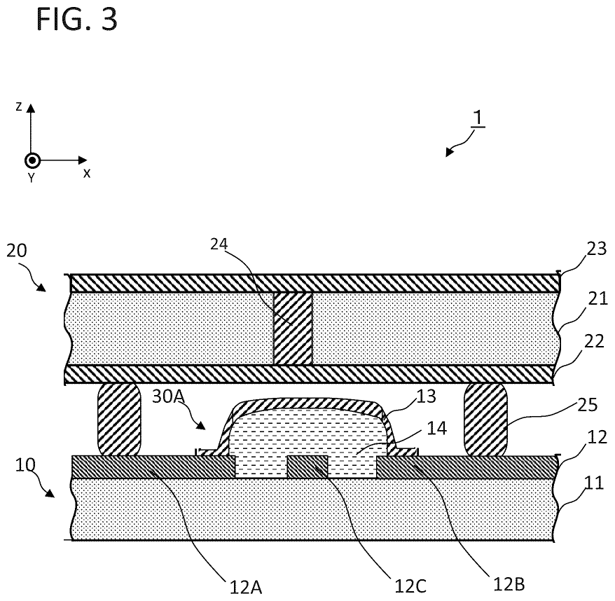

FIG. 3 is a schematic sectional view of an example in which a quantum chip 10 with an air bridge 30A is flip-chip mounted on an interposer 20, where the air bridge 30A is formed on a wiring layer 12 on a first side produced by the manufacturing processes as illustrated in FIGS. 1A to 2H. In the mounting stage, a wiring pattern has already been formed on a wiring layer 22 on a first surface of a board 21 of the interposer 20. A wiring pattern may have already been formed on a wiring layer 23 on a second side of the board 21. A through-hole via 24 penetrating through the board 21 may have also been formed. In addition, bumps (metal protrusions) 25 may have already been formed on the wiring layer 22 on the first surface of the interposer 20 or on the wiring layer 12 of the quantum chip 10. In a case where the board 11 of the quantum chip 10 is made of silicon, the board 21 of the interposer 20 may also be made of silicon. It is noted that a material of the board 21 is not limited to silicon. The board 21 may be made of material such as sapphire, compound semiconductor materials (group 4 elements, group III-V compounds, or group II-VI compounds), glass, or a ceramic material. Preferably, the wiring layer 22 on the first side and the wiring layer 23 on the second side may be made of the same superconducting material. In FIG. 3, although only one through-hole via 24 is illustrated, for simplicity's sake, a plurality of through-hole vias may be formed, such as a through-hole via connecting a signal line in the wiring layer 22 on the first surface of the interposer 20 and a signal line in the wiring layer 23 on the second side of the interposer 20 and a through-hole via connecting a ground plane in the wiring layer 22 on the first surface of the interposer 20 and a ground plane in the wiring layer 23 on the second side of the interposer 20. While the through-hole via 24 is illustrated as a via (a filled via), an inside of which is filled with a conductor, the through-hole via 24 may be a perforated via (a conformal via) in which a conductor having a uniform thickness is formed following a shape of the via hole. The side wall of the via may have a superconducting thin film such as a Ti or TiN film, and the inside of the via may be filled with Cu.

As illustrated in FIG. 3, the quantum chip 10 including a photoresist 14 (a sacrificial layer) underneath the air bridge 30A is flip-chip bonded (FCB) to the interposer 20 such that a first surface of the quantum chip 10 on which the air bridge 30A is formed faces the wiring layer 22 on the first surface of the interposer 20.

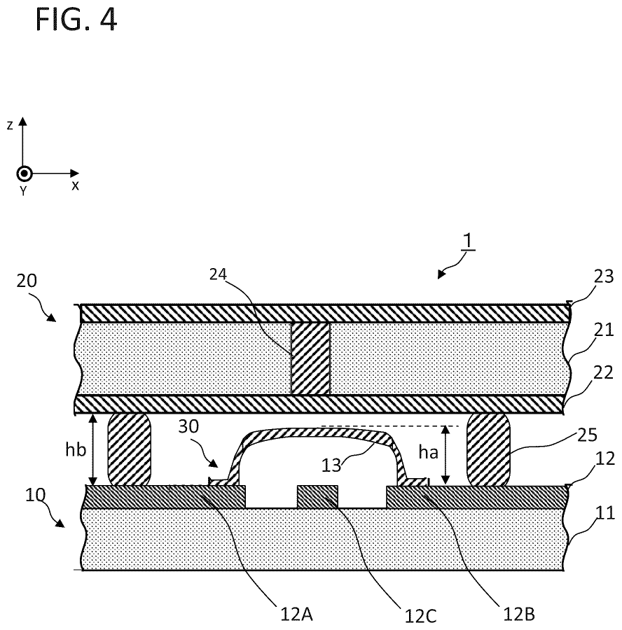

A superconducting circuit apparatus (a device) 1 obtained after completion of the flip-chip bonding of the quantum chip 10 to the interposer 20 is immersed in an organic solvent (stripping solution), to remove the photoresist 14 (sacrificial layer) underneath the air bridge 30A in FIG. 3. As needed, a dry process such as ashing may be performed to remove the photoresist 14 (sacrificial layer). As a result, as illustrated in FIG. 4, the superconducting circuit apparatus (device) 1 in which the quantum chip 10 including a hollow air bridge 30 is flip-chip mounted on the interposer 20 is obtained. In FIG. 4, the wiring layer 23 on the second side of the interposer 20 may be connected to, for example, a package board not illustrated.

In FIGS. 3 and 4, the bumps 25 are metal protrusions suitable for controlling an interval between the boards to be bonded, and may be formed to have an arbitrary shape, such as a columnar shape (a cylindrical shape or a polygonal shape), a cone shape (a truncated cone shape, a polygonal pyramid shape, or a truncated pyramid shape), a spherical shape, or a rectangular shape. The bumps 25 may be made of a normal conducting material and formed by laminates of superconducting materials. The bumps 25 may be formed on the wiring layer 22 on the first surface of the quantum chip 10. The bumps 25 may be formed on the wiring layer 22 on the first surface of the interposer 20. The bumps 25 may include the same superconducting material as that of the wiring layer 22 on the first surface of the interposer 20 or may include a superconducting material different from that of the wiring layer 22 on the first side.

A height of the bump 25 may be, for example, on the order of a few μ m to 10 μm, to implement signal transmission based on wireless transmission (e.g., capacitive coupling) between the interposer 20 and the quantum chip 10. In this case, a width of the bump 25 may be on the order of a few μ m to several tens of μ m. The bump 25 may also be termed as a micro bump.

The bump 25 may include a plurality of metal layers. The bump 25 may preferably include, as at least one of metal layers, a superconducting material. For example, the bump 25 may be made of a normal conducting material such as Cu or silicon dioxide (SiO₂) , and a surface of the bump 25 may be covered by a superconducting material film.

As illustrated in FIG. 4, a height of the air bridge 30 is set less than an interval between the quantum chip 10 and the wiring layer 22 on the first surface of the interposer 20 (a height hb of the bump 25), and the bridge girder of the air bridge 30 (13E in FIG. 10) is away from the wiring layer 22 on the first surface of the interposer 20 via an air gap. The length of the air bridge 30 is set to a value based on a space (interval) between a first conductor 12A and a second conductor 12B (W+2S, assuming that a width of a conductor 12C is W, a space between the first conductor 12A and the conductor 12C is S, and a space between the second conductor 12B and the conductor 12C is S).

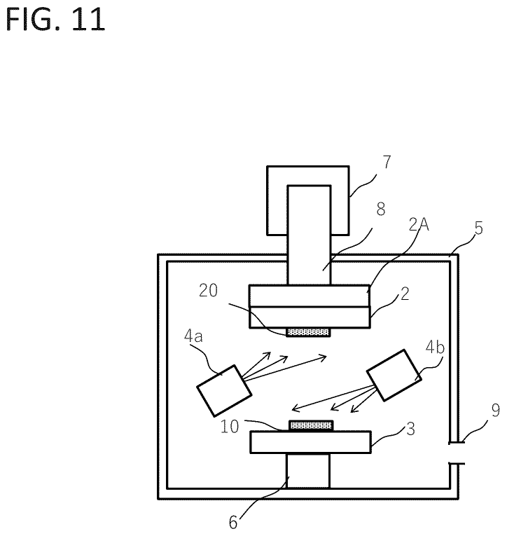

The quantum chip 10 may be flip-chip bonded to the interposer 20 using solid-phase bonding. Though not limited thereto, surface activated bonding (SAB) or the like may be performed as the solid-phase bonding. In this case, as a non-limiting example, as illustrated in FIG. 11, the interposer 20 and the quantum chip 10 are disposed in a vacuum chamber 5 such that the bumps 25 formed on the wiring layer 22 on the first surface of the interposer 20 face the electrode pads (to be bonded to the bumps 25) of the wiring layer 12 of the quantum chip 10, and evacuation of the chamber 25 is performed by a vacuum pump not illustrated through a vacuum exhaust port 9. The quantum chip 10 is fixed by a first fixture (stage) 2, for example. The fixing method may be a clamping method or an electrostatic chucking method. The quantum chip 10 fixed by the first fixture (stage) 2 may be in a wafer state or may be an individual chip that has been separated from a wafer. The interposer 20 (a wafer or an individual chip that has been separated from a wafer) is fixed by a second fixture (stage) 3 supported by a supporting portion 6. The fixing method may be a clamping method or an electrostatic chucking method. Each of the quantum chip 10 and the interposer 20, which is an individual chip that has been separated from a wafer, may be one that has been selected as a good device by a device testing such as a connection test performed before bonding. A degree of vacuum in the vacuum chamber 5 may be, for example, about 10⁻⁶ Pa (Pascal). An XY translation stage 2A enables the first fixture (holding member) 2 to perform translational movement in an X direction and in a Y direction with respect to the lower second fixture 3, and a Z-direction movement mechanism 7 and a Z-axis rotation mechanism 8 enable the first fixture (holding member) 2 to perform movement in a Z direction and positioning based on rotation about the Z axis. Using an activation apparatus 4a, absorbates and oxides on a surface of an electrode pad of the quantum chip 10 are removed, and a bonding portion of an electrode pad of the quantum chip 10 is activated. Using an activation apparatus 4b, absorbates and oxides on a surface of the bump 25 of the interposer 20 are removed, and a bonding portion the bump 25 of the interposer 20 to the quantum chip 10 is activated. As these activation apparatuses 4a and 4b, apparatuses that emit, for example, Ar (argon) ions or a neutral atom beam may be used.

Next, alignment between the quantum chip 10 and the interposer 20 is performed. This alignment may be performed by translational movement of the first fixture 2 in the X direction and in the Y direction with respect to the second fixture 3 and by rotation about the Z axis. With the degree of vacuum maintained, contact surfaces of the electrode pad of the wiring layer 12 of the quantum chip 10 and the contact surface of the bump 25 are brought into contact with each other, and pressure is applied by the Z-direction movement mechanism 7 (where the pressure is a hundred to several hundred MPa, though not limited to). A Z-axis pressure sensor not illustrated may measure the pressure in a direction perpendicular to the contact surfaces in contact with each other under pressure, and the application of the pressure may be controlled. The temperature may be room temperature or may be, for example, a low temperature equal to or less than 100° C. The bump 25 having ductility conform with roughness of the surface of the electrode pad of the quantum chip 10, and is strongly bonded to the bonding interface of the electrode pad of the quantum chip 10. For example, each of the quantum chip 10 and the interposer 20 may be provided with alignment markers (not illustrated), and a relative position may be adjusted by using transmission image captured by an infrared camera or the like. In this way, the positions of the quantum chip 10 and the interposer 20 may be adjusted. In a case where the quantum chip 10 and the interposer 20 are bonded in a wafer state, these wafers are first bonded to each other, and are next divided into chips.

Use of the above-described process enables flip-chip mounting of the quantum chip 10 including the air bridge 30 on the interposer 20.

To intentionally leave the photoresist 14 as the sacrificial layer, a width of the air bridge 30 may preferably be relatively wide, for example, 30 μm (micrometers) or greater. When an air bridge electrically connects ground planes on both sides of a signal line of a coplanar waveguide structure, a wider air bridge is more effective in resolving a bias of a distribution of electric charge that spreads on the ground planes during an operation of the quantum circuit, which may enhance a crosstalk reduction effect.

However, if the air bridge 30 has an excessively wide width, it is difficult to remove the sacrificial layer underneath the air bridge 30. In the air bridge manufacturing process, if a width of the superconducting member 13 (pattern formed using the photoresist 16), which is to serve as the air bridge, is increased, the width of the photoresist 14 (sacrificial layer) underneath the superconducting member 13 (pattern formed) also becomes large following the width of the superconducting member 13. When the photoresist 14 (sacrificial layer) left under the bridge 30A (FIG. 3) is removed after the quantum chip 10 is flip-chip bonded to the interposer 20, removal of the photoresist 14 (sacrificial layer) from the base portions (corners) of the wide bridge pier part of the air bridge 30A (FIG. 3) becomes difficult, and therefore, some of the photoresist 14 may tend to be left. The residual photoresist 14 (sacrificial layer) causes dielectric loss of a superconducting quantum circuit element to affect a yield. Because of restriction that the height of the air bridge 30 is equal to or less than the height of the bump 25, and a length of the air bridge 30 set in advance, an area of the hollow portion underneath the air bridge 30 cannot be increased widely. Thus, an upper limit of the width of the air bridge 30 may be determined in consideration of the area of the hollow portion underneath the air bridge 30 and removal of the photoresist 14 (sacrificial layer) left underneath the air bridge 30. A plurality of air bridges 30, each of which connects a pair of ground planes opposing each other via respective gaps from a signal line of a coplanar waveguide, may be juxtaposed for the coplanar waveguide.

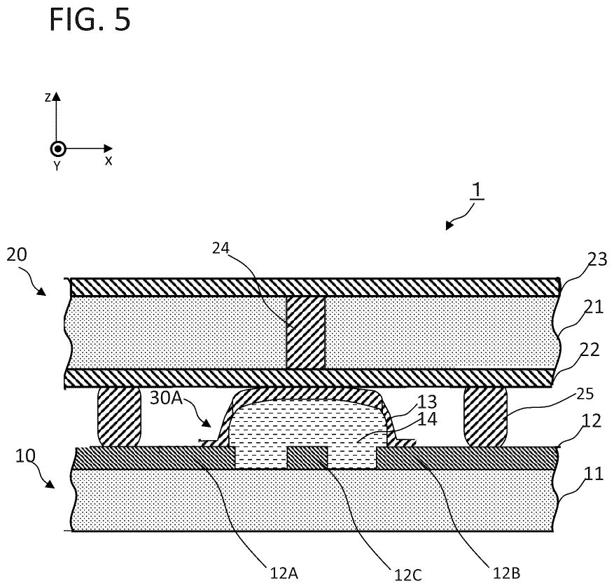

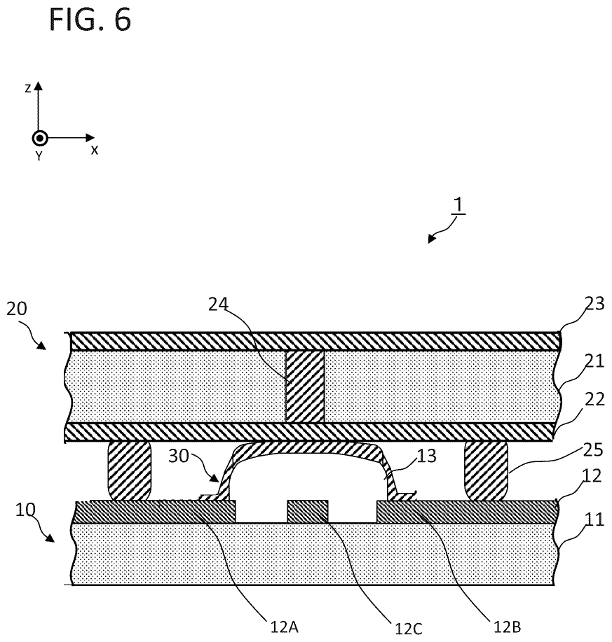

As another example air bridge of the present disclosure, as illustrated in FIG. 5, at least a top portion of the air bridge 30A may be in contact with the interposer 20. Since the photoresist 14 is left underneath the air bridge 30A to support the air bridge 30A from underneath, this mounting is possible. In the example in FIG. 5, the bridge girder part (13E in FIG. 10) of the wiring (superconductor) 13 constituting the air bridge 30A faces and is in contact with the first wiring layer 22 of the interposer 20 with a predetermined width. Alternatively, for example, part of the bridge girder part (or a point thereof), such as the top portion of the bridge girder part, may be in contact with the first wiring layer 22 of the interposer 20. FIG. 6 schematically illustrates a state in which the photoresist 14 underneath the air bridge 30A in FIG. 5 has been removed (the air bridge 30 having a hollow structure thereunder). In FIG. 6, the first conductor 12A and the second conductor 12B, each of which is disposed to face the signal conductor 12C of the quantum chip 10 via a gap, are ground planes, and constitutes a coplanar waveguide. The wiring (superconductor) 13 constituting the air bridge 30 not only electrically connects the ground plane (the first conductor 12A) and the ground plane (the second conductor 12B) that are separated from each other via the signal conductor 12C of the quantum chip 10, but also is, in contact with and electrically connects to, a ground plane of the wiring layer 22 on the first surface of the interposer 20. The air bridge 30 provides a connection path between the ground planes (the first and second conductors 12A and 12B) of the quantum chip 10 and the ground plane of the wiring layer 22 on the first surface of the interposer 20.

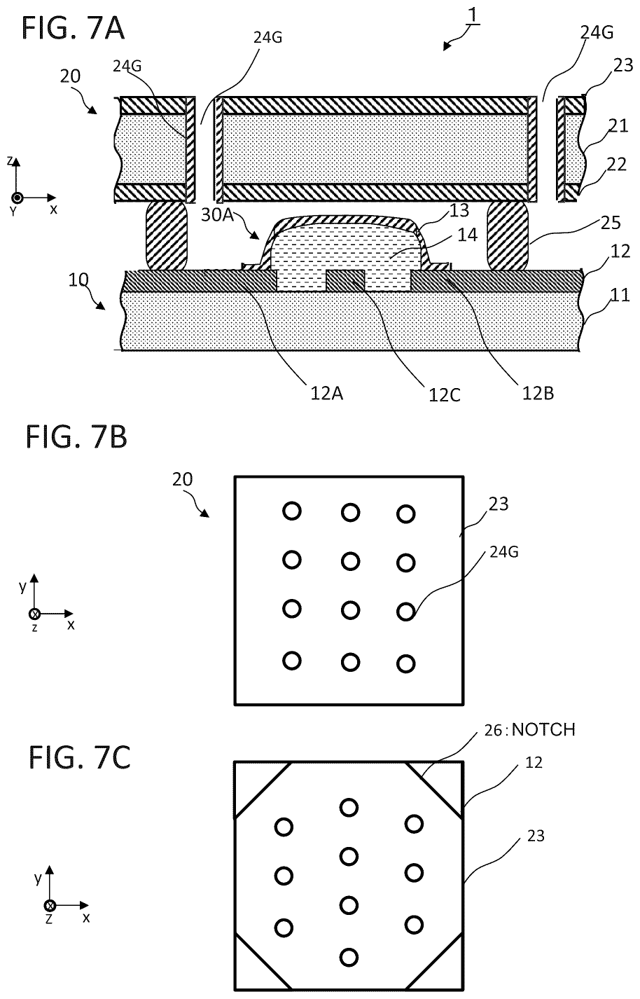

FIGS. 7A to 7C schematically illustrate, as another mode of the present disclosure, a structure which facilitates immersion of organic solvent or oxygen plasma gas to remove the photoresist 14 (sacrificial layer) immediately underneath the air bridge 30A after flip-chip mounting of the chip. In FIG. 7A, a through-hole via (a ground via) that connects the ground plane of the wiring layer 22 on the first surface of the interposer 20 and the ground plane of the wiring layer 23 on the second surface is formed with a conductive layer such as Al or Cu having a preset plating film thickness. The through-hole via is a via (conformal via) 24G extending from the wiring layer 22 on the first surface to the wiring layer 23 on the second surface. When the photoresist 14 (sacrificial layer) immediately underneath the air bridge 30A is removed, the organic solvent or the oxygen plasma gas easily permeates from the opening portion of the individual through-hole via 24G as well. A diameter of through-hole via 24G may be on the order of ten μ m.

FIG. 7B schematically illustrates an arrangement example of the through-hole vias (ground vias) 24G of FIG. 7A, seen from the wiring layer 23 on the second surface of the interposer 20. In an array of the through-hole vias (ground vias) 24G, the pitch may be about 1/20 of a signal wavelength λ or less than 1/20 of the signal wavelength λ (if the wavelength λ of signal frequency 1GHz (giga-hertz) is 3 cm (centimeters), the pitch is approximately 750 μ m or less at 20 GHz). At least one through-hole via (ground via) 24G may be formed near each qubit disposed in the quantum chip 10. By disposing the array of through-hole vias (ground vias) 24G as hollow spaces penetrating through the interposer 20, organic solvent or oxygen plasma gas can be not only immersed laterally from a side surface (gap between the quantum chip 10 and the interposer 20), but also immersed uniformly in a vertical direction from the second wiring layer 23 of the interposer 20. Thus, the photoresist 14 (sacrificial layer) can be quickly removed. The arrangement of the through-hole vias (ground vias) 24G is not limited to a regular allay. The through-hole vias (ground vias) 24G may, as a matter of course, be disposed in any pattern.

FIG. 7C illustrates an example in which a notch 26 is formed in each of the four corners of the interposer 20 such that organic solvent or oxygen plasma easily permeates and the photoresist 14 (sacrificial layer) left underneath the air bridge 30A is removed. Locations of these notches 26 are not limited to the four corners. A notch 26 may be formed, for example, on a side adjacent to an unused area of the interposer 20. When the wiring layer 12 of the quantum chip 10 includes an unused area, a cavity penetrating through the board 21 may be formed in an area corresponding to the unused area of the interposer 20. FIG. 7C illustrates an example in which a planar shape of the quantum chip 10 and a planar shape of the interposer 20 have the same size, for ease of description. However, the present disclosure is of course not limited to this structure.

The air bridge of the present disclosure can be used as a multilayer wiring that does not use an inter-layer insulating film that could incur dielectric loss. The air bridge can be also considered as an inter-layer insulating film structure that uses air and can form a low-capacitance wiring having a relative permittivity of 1. Regarding a layout of the wiring layer 12 of the quantum chip 10, in a case where a signal wiring to a qubit or a coupler crosses another signal wiring, a three-dimensional wiring structure may be used in which the signal wiring is connected via a bump to the wiring layer 22 on the first surface of the interposer 20 and routed on the wiring layer 22 of the interposer 20, with the wiring on the wiring layer 22 of the interposer 20 connected via a bump back to the wiring layer 12 of the quantum chip 10.

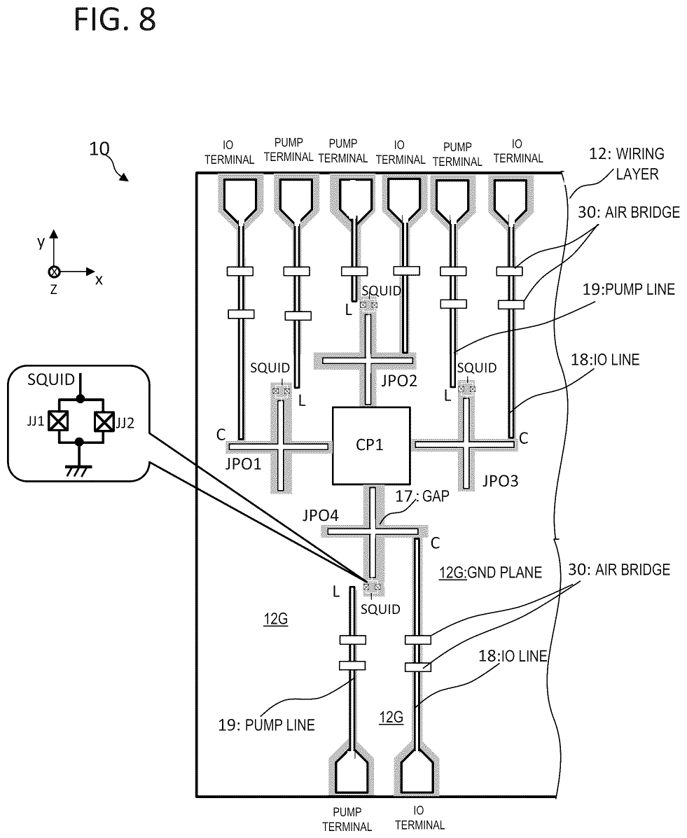

FIG. 8 schematically illustrates an example of a wiring pattern of a wiring layer 12 of a quantum chip 10. As described above, the quantum chip 10 is flip-chip mounted on an interposer 20. In FIG. 8, for ease of description, the quantum chip 10 includes terminals on peripheries thereof. In the example illustrated in FIG. 8, a Josephson parametric oscillator (JPO) is used as an individual qubit included in a superconducting circuit of the quantum chip 10. A coupler CP1 realizes four-body interaction of four nearest-neighbors JPO1 to JPO4 (illustration of other JPOs and couplers is omitted). An individual JPO may have a cross-shaped electrode having four arms and is surrounded by ground planes 12G of the wiring layer 12 via a gap 17. The individual JPO may have a SQUID including a loop with Josephson junctions JJ1 and JJ2 arranged therein. An individual IO (input-output) line 18 extending from an IO terminal has a coplanar waveguide structure and has an end portion, as a coupling port C, capacitively coupled to an electrode of a JPO. An individual pump line 19 extending from a pump terminal has a coplanar waveguide structure and has an end portion, as a coupling port L, electromagnetically or inductively coupled to the SQUID of a JPO to apply a magnetic field thereto. The individual IO line 18 is used for transmission of a signal to a JPO and for transmission of a signal (reflected signal) from a JPO. The individual pump line 19 is used for transmission of a microwave signal for generating a magnetic field applied to a SQUID. The IO lines 18 and the pump lines 19 are each provided with one or more air bridges 30, each striding over a signal line and electrically connecting two ground planes 12G disposed opposing each other on both longitudinal sides of the signal line. The coupler CP1 may be configured to have a Josephson junction(s). Alternatively, the coupler CP1 may be configured to have a SQUID(s). In this case, a control line for transmission of a direct-current bias signal to apply a bias magnetic field to the SQUID of the coupler CP1 may be provided. The IO line 18 and the pump line 19 provided for an individual JPO in FIG. 6 extend to an IO terminal and a pump terminal with a space therebetween, respectively such that the IO line 18 and the pump line 19 do not cross each other. In FIG. 6, if an IO line 18 and a pump line 19 of the quantum chip 10 are to be formed to cross each other, a three-dimensional wiring structure may be used. For example, one of the lines is extended to the wiring layer 22 on the first surface of the interposer 20 via a bump, is routed in the wiring layer 22 on the first surface of the interposer 20 and then is returned back to the wiring layer 12 of the quantum chip 10 via a bump.

Alternatively, a signal wiring may be routed to cross another signal wiring in the air by using an air bridge. For example, in FIG. 10, assuming that the first conductor 12A and the second conductor 12B are to constitute a first signal line conductor for transmission of a first signal, and the conductor 12C is a second signal line conductor for transmission of a second signal, the air bridge 30 strides over the second signal line conductor 12C and allows the first signal line conductor and the second signal line conductor to cross each other via an air gap.

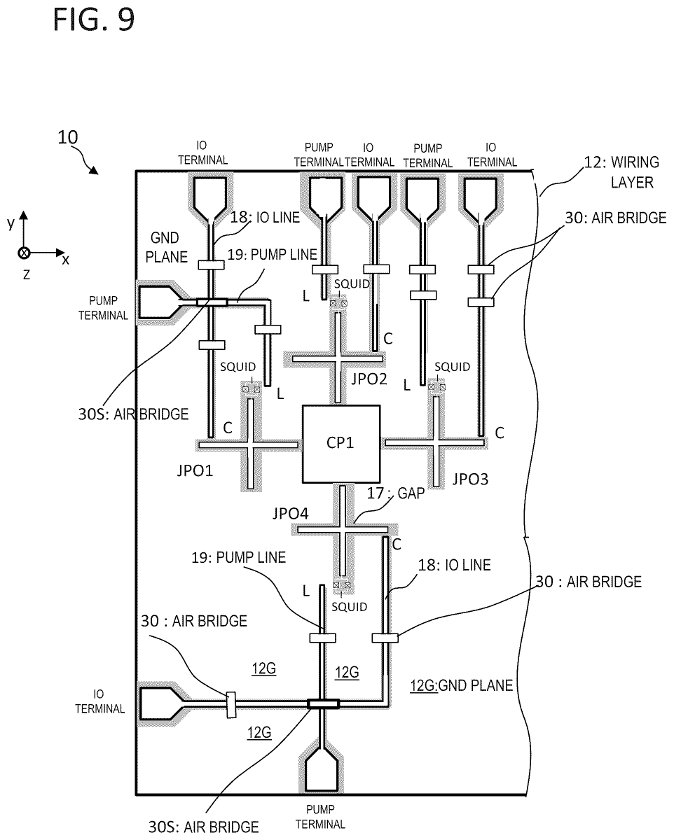

As illustrated in FIG. 9, unlike the configuration in FIG. 8, the quantum chip 10 includes an air bridge(s) 30S such that signal lines are enabled to cross one another on the wiring layer 12 of the quantum chip 10. The pump line 19 that connects an inductive coupling port (L port) of the JPO1 and a pump terminal uses an air bridge 30S striding over the IO line 18 that connects a capacitive coupling port (C port) of the JPO1 and an IO terminal. The IO line 18 that connects a C port of the JPO4 and an IO terminal uses an air bridge 30S striding over the pump line 19 that connects an L port of the JPO4 and a pump terminal. A width of the air bridge 30S is set to be the same as a width of the center conductor of the corresponding coplanar waveguide structure (the conductor 12C in FIG. 10) (e.g., when a line width of the center conductor is 10 μ m, the width of the air bridge 30S is set to 10 μ m). As with a case of an air bridge 30 striding over a signal wiring to connect ground planes opposing each other via respective gaps from the signal wiring, an air bridge 30S that allows signal wirings to three-dimensionally cross each other is also flip-chip mounted on the interposer 20 with the photoresist (the sacrificial layer) left underneath the air bridge 30S, and then after the photoresist (the sacrificial layer) underneath the air bridge 30S is removed. In addition to the three-dimensional wiring structure where the quantum chip 10 and the interposer 20 are stacked, another three-dimensional wiring structure using an air bridge(s) can be realized. Thus, a degree of freedom in placement and routing in the quantum chip 10 can be enhanced. In addition, signal lines can be crossed with no bypass wiring via bumps and by the interposer 20 needed, or with a reduced number of these bypass wirings. As a result, the wiring area of the interposer 20 can be effectively used.

In the above-described examples, a single chip with an air bridge(s) is mounted on an interposer. A plurality of chips (at least one of which includes an air bridge) may, as a matter of course, be mounted in juxtaposition on a single interposer. In addition, the present disclosure is applicable to a three-dimensional chip structure in which a plurality of chips (at least one of which includes an air bridge) are vertically stacked on an interposer. The present disclosure is also applicable to a structure in which a chip (a daughter chip) is stacked on a base chip (a mother chip) face-to-face via a bump (also referred to as “chip-on-chip”). The above-described flip-chip mounting examples may be said to correspond to one that a base chip in a chip-on-chip structure is an interposer. In addition, the examples described above are applicable not only to a superconducting quantum circuit but also to a three-dimensional MMIC (Monolithically Integrated Microwave Integrated Circuit), etc.

The above-described examples and embodiments can be described, but not limited to, as the following notes.

(Note 1) A device, including: a chip with at least one air bridge formed on a first surface thereof; and a board with the chip mounted thereon, the first surface of the chip being opposed to the board.

(Note 2) In the device according to note 1, the air bridge is spaced from the first surface of the board, in a height direction.

(Note 3) In the device according to note 1, at least part of the air bridge is in contact with the board.

(Note 4) In the device according to any one of notes 1 to 3, the chip includes, on the first surface, the air bridge that strides over a conductor extending in a predetermined direction and electrically connects a first ground conductor and a second ground conductor disposed via respective gaps from the conductor on longitudinal sides of the conductor.

(Note 5) In the device according to any one of notes 1 to 4, the first surface of the chip and the board are bonded to each other via a bump(s).

(Note 6) In the device according to any one of notes 1 to 5, the chip includes a superconducting quantum circuit on the first surface, and the air bridge is formed by a superconducting member.

(Note 7) In the device according to any one of notes 1 to 6, the chip with the air bridge in a state that a sacrificial layer formed by a photoresist is left underneath the air bridge is flip-chip mounted on the board, the sacrificial layer underneath the air bridge being removed after the flip-chip mounting.

(Note 8) A device manufacturing method comprising:
forming(depositing) a conductive layer, which is to be an air bridge, on a sacrificial layer in a first surface of a chip to pattern form the conductive layer, and
removing the sacrificial layer other than the sacrificial layer underneath the air bridge;
mounting the chip with the sacrificial layer left underneath the air bridge on a board, with the first surface of the chip opposed to the board; and
removing the sacrificial layer left underneath the air bridge.

(Note 9) In the device manufacturing method according to note 8, as a path for gas and/or solvent for removing the sacrificial layer left underneath the air bridge, at least one of a through-hole via, a notch, and a cavity formed in the board is used in addition to a gap between the chip and the board.

(Note 10) In the device manufacturing method according to note 8 or 9, in a state in which the chip is mounted on the board and the first surface opposes the board, the air bridge is spaced apart from the board, in a height direction.

(Note 11) In the device manufacturing method according to any one of notes 8 to 10, the sacrificial layer is formed by a photoresist.

The disclosure of each of the above PTLs 1 and 2 is incorporated herein by reference thereto. Modifications and adjustments of the example embodiments or examples are possible within the scope of the overall disclosure (including the claims) of the present invention and based on the basic technical concept of the present invention. Various combinations or selections of various disclosed elements (including the elements in each of the notes, examples, diagrams, etc.) are possible within the claims of the present invention. That is, the present invention of course includes various variations and modifications that could be made by those skilled in the art according to the overall disclosure including the claims and the technical concept.

What is claimed is:

1. A device comprising:
a chip with at least one air bridge formed on a first surface of the chip; and
a board with the chip mounted thereon, the first surface of the chip opposed to the board.

2. The device according to claim 1, wherein the air bridge is spaced apart via an air gap from the board in a height direction.

3. The device according to claim 1, wherein at least part of the air bridge is in contact with the board.

4. The device according to claim 1, wherein the air bridge strides over a conductor extending in a predetermined direction and electrically connects a first ground conductor and a second ground conductor disposed via respective gaps from the conductor on longitudinal sides of the conductor.

5. The device according to claim 1, wherein the air bridge strides over a second conductor extended in a predetermined direction and electrically connects a first part and a second part of a first conductor disposed via respective gaps on both sides of the second conductor to make the first conductor cross the second conductor spaced with an air gap therebetween.

6. The device according to claim 1, wherein the first surface of the chip and the board are bonded via one or more bumps provided therebetween.

7. The device according to claim 1, wherein the chip includes
a superconducting quantum circuit on the first surface thereof, the air bridge being made of a superconducting material.

8. The device according to claim 1, wherein the chip with the air bridge in a state that a sacrificial layer formed by a photoresist is left underneath the air bridge is mounted on the board, the sacrificial layer underneath the air bridge removed after mounting of the chip on the board.

9. A device manufacturing method comprising:
forming a conductive layer, which is to be an air bridge, on a sacrificial layer in a first surface of a chip to pattern-form the conductive layer;
removing the sacrificial layer other than the sacrificial layer underneath the air bridge;
mounting the chip with the sacrificial layer left underneath the air bridge on a board such that the first surface opposes the board; and
removing the sacrificial layer left underneath the air bridge.

10. The device manufacturing method according to claim 9, comprising
using, as a path for gas and/or solvent for removing the sacrificial layer left underneath the air bridge, at least one of a through-hole via, a notch, and a cavity formed in the board and a gap between the chip and the board.

11. The device manufacturing method according to claim 9, wherein in a state in which the chip is mounted on the board with the first surface of the chip opposed to the board,
the air bridge is spaced apart from the board in a heigh direction via an air gap.

12. The device manufacturing method according to claim 9, wherein in a state in which the chip is mounted on the board with the first surface of the chip opposed to the board,
at least part of the air bridge is in contact with the board.

13. The device manufacturing method according to claim 9, wherein the sacrificial layer is formed by a photoresist.
